(19) United States
(12) Patent Application Publication
(10) Pub. No.: US 2024/0051068 A1
(43) Pub. Date: Feb. 15, 2024

(54) TRANSFER APPARATUS AND TRANSFER METHOD

(71) Applicant: SHIN-ETSU ENGINEERING CO., LTD., Tokyo (JP)

(72) Inventors: Yoshikazu OHTANI, Gunma (JP); Michiya YOKOTA, Gunma (JP); Ryouichi INABA, Gunma (JP)

(73) Assignee: SHIN-ETSU ENGINEERING CO., LTD., Tokyo (JP)

(21) Appl. No.: 18/283,359

(22) PCT Filed: Apr. 30, 2021
(86) PCT No.: PCT/JP2021/017228

§ 371 Date: Sep. 21, 2023

(51) Int. Cl. B23K 26/402

(52) U.S. Cl. CPC B23K 26/402; B23K 2101/40

(57) ABSTRACT

A transfer apparatus includes the first plate-like member in which the micro structures are detachably held via the temporary adhesion layer, the second plate-like member having a sticky layer which faces the first plate-like member and is elastically deformable in a thickness direction, a pressure part which presses one of the first plate-like member and the second plate-like member toward another one of the first plate-like member and the second plate-like member in the thickness direction such that the temporary adhesion layer and the sticky layer become parallel to each other at least locally, a denaturing/peeling part which changes properties of the temporary adhesion layer such that an adhesive force of the temporary adhesion layer is reduced, and a controlling part which controls operations of the pressure part and the denaturing/peeling part.

### TECHNICAL FIELD

The present invention relates to a transfer apparatus used for transferring micro structures constituted of micro structure bodies including micro elements such as micro LEDs or microchips and micro insulating pieces including small glass pieces, and a transfer method which uses the transfer apparatus.

### BACKGROUND ART

Conventionally, as such a transfer apparatus and such a transfer method, there is a supporting body separation method including a light irradiation process of irradiating, in a circular laminated body in which a circular substrate and a supporting body through which light passes are laminated via an adhesion layer and a separation layer of which properties are changed by absorption of light, light to at least part of the separation layer laminated in a predetermined area in a radial direction of the substrate via the supporting body, and a separation process of applying a force to the laminated body, to which light is irradiated, to separate the supporting body from the laminated body (see, e.g., PTL 1).

The predetermined area in the radial direction of the substrate is an (annular) area which surrounds the entire periphery of a circuit formation area in an inner peripheral part of the substrate, and occupies an area of not less than 65% and less than 100% of a width in a radial direction of a non-circuit formation area outside the circuit formation area. Further, the predetermined area is constituted of divided predetermined areas (fan-shaped divided areas) obtained by equally dividing the predetermined area (in a circumferential direction) at a predetermined angle about the center point of the laminated body.

In the light irradiation process, by repeating a light irradiation step of irradiating laser light to each divided area from a laser irradiation apparatus and a rotation step of rotating the laminated body by a predetermined angle in the circumferential direction alternately, the laser light is irradiated to all of the divided areas and properties of part of the separation layer are changed annularly, or the laser light is irradiated to only part of a plurality of the divided areas which are disposed at regular intervals in the circumferential direction and properties of part of the separation layer in a fan shape are changed.

In the separation step, after part of the separation layer of which properties are changed is destroyed by separating the supporting body (support plate) from the laminated body and concentrating a force on part of the separation layer of which properties are changed, the force is concentrated on the other part of the separation layer in an area to which the laser light is not irradiated, and the support plate can be thereby separated from the laminated body.

In addition, in some material layer separation methods in each of which a GaN layer is separated from a sapphire substrate by irradiating laser light to an interface between the sapphire substrate and a section as laser lift-off, the shape of a beam spot (laser beam) is limited by a beam homogenizer (see, e.g., PTL 2).

With regard to the shape limitation of the laser beam, by performing irradiation which surrounds the separated section correspondingly to an LED die (chip), the laser beam is formed substantially uniformly. Accordingly, a shock wave by the irradiation with the laser light is alleviated, and fractures in the LED chip and the GaN layer during a lift-off process are reduced.

### CITATION LIST

### Patent Literature

[PTL 1] Japanese Patent Application Publication No. 2017-084910
[PTL 2] Japanese Translation of PCT Application No. 2007-534164

### SUMMARY OF INVENTION

### Technical Problem

Incidentally, in the case where laser light is used as light irradiated to the laminated body from a light irradiation part, it is not easy to perform adjustment for setting a focal position of the laser light to the separation layer of the laminated body in which plastic deformation such as warpage or roughness is present and it has been extremely difficult to evenly irradiate the laser light to the entire face of the separation layer to separate (peel) the separation layer.

However, in the method described in PTL 1, the laser light is irradiated to at least only part of the separation layer laminated in the predetermined area constituted of the divided predetermined areas in the radial direction in the substrate via the supporting body, and hence the laser light is not irradiated to the entire separation layer.

Consequently, irradiation unevenness of the laser light to the separation layer of the laminated body is apt to occur partially, which presents a problem in which peeling failure occurs partially in a portion where laser output is insufficient or a portion to which the laser light is not irradiated in the separation layer, a problem in which a device formed on a circuit substrate of a chip mounted on the substrate is damaged in a portion where laser output is excessively high conversely, and a problem in which generation of soot by excessive irradiation of the laser light occurs.

In particular, in the case where the laminated body has even slight plastic deformation such as warpage or roughness, when the laser light is irradiated to the laminated body from the edge thereof continuously and peeling is thereby performed successively, internal stress caused by the plastic deformation such as warpage or roughness is locally released in a continuous wide area, and hence a problem arises in that a crack is formed at an interface with an area to which the laser light is not irradiated, the device formed on the circuit substrate of the chip mounted on the substrate is damaged, or, at worst, the laminated body is broken.

In addition, in the method described in PTL 2, the beam homogenizer corresponding to the size and the location of the LED chip is used, and hence a problem arises in that the shape of the laser beam is limited.

### Solution to Problem

In order to solve such a problem, a transfer apparatus according to the present invention is a transfer apparatus in which at least one micro structures attached to a first plate-like member are peeled from the first plate-like member, and is bonded and transferred to a second plate-like member facing the first plate-like member, the transfer apparatus including: the first plate-like member in which the at least one micro structures are detachably held via a temporary adhesion layer; the second plate-like member having a sticky layer which faces the first plate-like member and is elastically deformable in a thickness direction; a pressure part which presses one of the first plate-like member and the second plate-like member toward another one of the first plate-like member and the second plate-like member in the thickness direction such that the temporary adhesion layer and the sticky layer become parallel to each other at least locally; a denaturing/peeling part which changes a property of the temporary adhesion layer such that an adhesive force of the temporary adhesion layer is reduced; and a controlling part which controls operations of the pressure part and the denaturing/peeling part, wherein the controlling part performs control such that the property of the temporary adhesion layer is changed by the denaturing/peeling part in a state in which surface of the at least one micro structures are pressed into the sticky layer by the pressure part and the surface of the micro structure is embedded in the sticky layer.

In addition, in order to solve such a problem, a transfer method according to the present invention is a transfer method which peels at least one micro structures attached to a first plate-like member from the first plate-like member, and bonds and transfers the at least one micro structures to a second plate-like member facing the first plate-like member, the transfer method including: a setting process of disposing the first plate-like member and the second plate-like member such that the first plate-like member having a temporary adhesion layer faces the second plate-like member having a sticky layer; a pressing process of pressing one of the first plate-like member and the second plate-like member toward another one of the first plate-like member and the second plate-like member in a thickness direction such that the temporary adhesion layer and the sticky layer become parallel to each other at least locally; and a denaturing process of changing a property of the temporary adhesion layer such that an adhesive force of the temporary adhesion layer is reduced, wherein surface of the at least one micro structures are pressed by a pressure part so as to be embedded in the sticky layer in the pressing process, and the property of the temporary adhesion layer is changed by a denaturing/peeling part in a state in which the surface of the at least one micro structures are embedded in the sticky layer in the denaturing process.

Herein, “parallel to each other at least locally” means that part of the temporary adhesion layer and part of the sticky layer which are pressed are parallel to each other partially, and also includes that the entire temporary adhesion layer and the entire sticky layer are parallel to each other completely.

### BRIEF DESCRIPTION OF DRAWINGS

FIG. 1 is an explanatory view showing an entire configuration of a transfer apparatus according to an embodiment (first embodiment) of the present invention, and FIG. 1 at (a) is a transverse plan view, FIG. 1 at (b) is a partially cutaway front view, and FIG. 1 at (c) is a partially cutaway front view in which a principal portion is partially enlarged.

FIG. 2 is an explanatory view showing a transfer method according to the embodiment (first embodiment) of the present invention, and FIG. 2 at (a) is a partially cutaway front view of a carrying-in process, and FIG. 2 at (b) is a partially cutaway front view of a setting process and a pressing process.

FIG. 3 at (a) is a partially cutaway front view of a denaturing process, and FIG. 3 at (b) is a partially cutaway front view of a release process.

FIG. 4 at (a) is a partially cutaway front view of a primary carrying-out process, and FIG. 4 at (b) is a partially cutaway front view of a secondary carrying-out process.

FIG. 5 is an explanatory view showing an entire configuration of a transfer apparatus according to another embodiment (second embodiment) of the present invention, and is a partially cutaway front view in which a principal portion is partially enlarged.

FIG. 6 is an explanatory view showing an entire configuration of a transfer apparatus according to another embodiment (third embodiment) of the present invention, and is a partially cutaway front view in which a principal portion is partially enlarged.

FIG. 7 is an explanatory view showing an entire configuration of a transfer apparatus according to another embodiment (fourth embodiment) of the present invention, and is a partially cutaway front view in which a principal portion is partially enlarged.

FIG. 8 is an explanatory view showing an entire configuration of a transfer apparatus according to another embodiment (fifth embodiment) of the present invention, and is a partially cutaway front view in which a principal portion is partially enlarged.

FIG. 9 is an explanatory view showing an entire configuration of a transfer apparatus according to another embodiment (sixth embodiment) of the present invention, and is a partially cutaway front view in which a principal portion is partially enlarged.

FIG. 10 is an explanatory view showing an entire configuration of a transfer apparatus according to another embodiment (seventh embodiment) of the present invention, and is a partially cutaway front view in which a principal portion is partially enlarged.

### DESCRIPTION OF EMBODIMENTS

Hereinbelow, embodiments of the present invention will be described in detail based on the drawings.

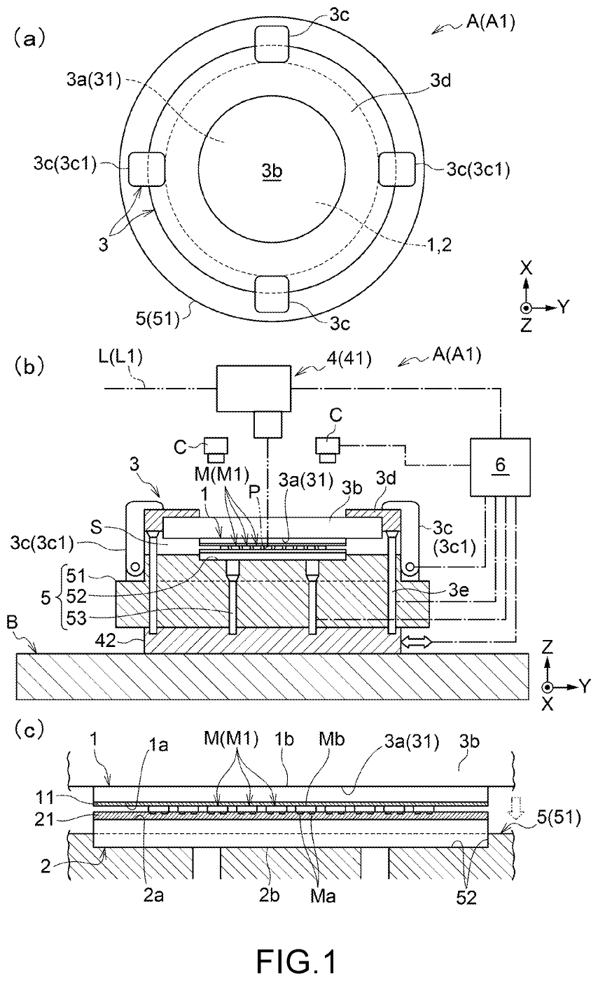

As shown in FIGS. 1 to 10, a transfer apparatus A and a transfer method according to the embodiments of the present invention are a micro structure manufacturing apparatus for peeling micro structures M attached to one of a first plate-like member 1 and a second plate-like member 2 which face each other, and bonding and transferring the micro structures M to the other one of the first plate-like member 1 and the second plate-like member 2, and a micro structure manufacturing method which uses the micro structure manufacturing apparatus.

The transfer apparatus A and the transfer method described above are used in a treatment process of a semiconductor wafer having an extremely thin thickness (ultra thin wafer) and are also used for manufacturing a semiconductor package such as a WLP (wafer level packaging) or a PLP (panel level packaging).

Note that the first plate-like member 1 and the second plate-like member 2 are housed in a space S, and peeling and bonding of the micro structures M are performed inside the space S and the micro structures M are transferred. Normally, the first plate-like member 1 and the second plate-like member 2 are disposed so as to face each other in a vertical direction, and a thickness direction of each of the first plate-like member 1 and the second plate-like member 2 is hereinafter referred to as “Z direction”. Directions extending along the first plate-like member 1 and the second plate-like member 2 which intersect the Z direction are hereinafter referred to as “XY directions”.

In the case of each of examples shown in FIGS. 1 to 9, the first plate-like member 1 serving as a transfer source is disposed in an upper part, and the second plate-like member 2 serving as a transfer destination is disposed in a lower part. That is, the micro structures M are detachably bonded to and held in the first plate-like member 1 serving as the transfer source.

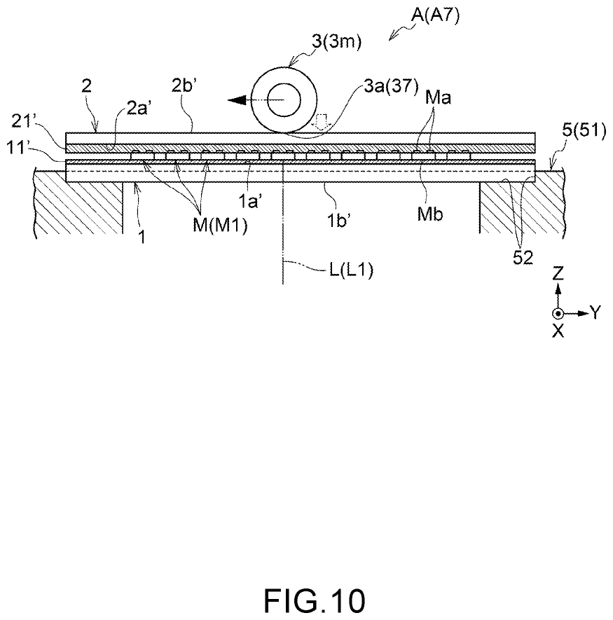

In addition, in the case of the example shown in FIG. 10, the first plate-like member 1 serving as the transfer source is disposed in the lower part, and the second plate-like member 2 is disposed in the upper part.

More specifically, the transfer apparatus A according to the embodiment of the present invention includes, as main constituent elements, the first plate-like member 1 which is provided to detachably hold the micro structures M with a temporary adhesion layer 11, the second plate-like member 2 which is provided to face the first plate-like member 1, a pressure part 3 which is provided to press one of the first plate-like member 1 and the second plate-like member 2 toward the other one thereof in the thickness direction (Z direction), and a denaturing/peeling part 4 which is provided to change properties (denature) of the temporary adhesion layer 11.

In addition, the transfer apparatus A includes a transport mechanism (not shown) which transports the first plate-like member 1 and the second plate-like member 2 to an apparatus main body B, a supporting part 5 which supports the first plate-like member 1 and the second plate-like member 2 which are transported toward the apparatus main body B, and a controlling part 6 which controls operations of the pressure part 3 and the denaturing/peeling part 4 or the like.

The micro structures M are constituted by micro structure bodies M1 including micro elements such as micro LEDs or microchips, micro insulating pieces including small glass pieces, and micro components similar to the micro structure bodies M1 and the micro insulating pieces. In particular, as shown in the drawings, a plurality of the micro structure bodies M1 are often aligned and disposed so as to be mounted in parallel with each other at predetermined intervals on the first plate-like member 1.

The first plate-like member 1 is constituted by a donor substrate which is formed into a plate shape with transparent or translucent glass, ceramic, a rigid material such as hard synthetic resin such as acrylic-based resin or opaque hard synthetic resin.

The overall shape of the first plate-like member 1 is formed into a circular wafer shape or a rectangular (a quadrangle having right-angled corners including a rectangle and a square) panel shape.

In the first plate-like member 1, a first opposite face 1a which faces the second plate-like member 2 in the thickness direction (Z direction) is formed as a smooth face as a whole, and has the temporary adhesion layer 11 to which the micro structures M are detachably bonded.

The temporary adhesion layer 11 has a proper adhesive force and is made of a denatured material which is denatured (change of properties) so as to be able to control the adhesive force of the temporary adhesion layer 11, and is formed along the first opposite face 1a of the first plate-like member 1 so as to have a uniform thickness.

The denatured material of the temporary adhesion layer 11 is constituted by photoreactive resin or the like. As a method of controlling the adhesive force of the denatured material, there is used a method in which the adhesive force is reduced by absorption of light L or the like such that the micro structures M can be peeled. Examples of the light L which changes the properties of the denatured material of the temporary adhesion layer 11 include a laser beam L1, a heat ray (infrared light), and other beams, and a beam having a high energy density can be irradiated to an object, and hence, among them, it is preferable to use the laser beam L1. Further, it is preferable to use, as the denatured material of the temporary adhesion layer 11, a material which can be easily washed away and removed after the micro structures M are peeled.

Incidentally, an example of a manufacturing method of the micro LED serving as the micro structures M (micro structure bodies MD includes laser lift-off (LLO) in which the laser beam L1 is irradiated to a device layer (gallium nitride-based compound crystal layer) laminated on a translucent member (sapphire substrate) from the translucent member, and an interface portion between the translucent member and the device layer is peeled.

In the case where the LLO is used as a specific example of the temporary adhesion layer 11, after a gallium nitride layer (the temporary adhesion layer 11) is grown on the sapphire substrate (the first plate-like member 1), the gallium nitride layer absorbs the laser beam L1 with the irradiation with the laser beam L1 from the side of the sapphire substrate to be caused to resolve into gallium (Ga) and nitrogen (N₂), the interface portion between the gallium nitride layer and the sapphire substrate is peeled, and it becomes possible to separate the gallium nitride-based compound crystal layer (the micro structures M) from the sapphire substrate. In this case, the first plate-like member 1 is formed into a circular wafer shape shown in the example in the drawing.

In addition, in another example of the temporary adhesion layer 11, the micro structures M (the micro structure bodies M1, the micro insulating piece, and the micro component) is temporarily attached to the first opposite face 1a of the first plate-like member 1 with the temporary adhesion layer 11 interposed therebetween, properties of the temporary adhesion layer 11 are changed by the irradiation of the temporary adhesion layer 11 with the light L including the laser beam L1, the heat ray (infrared light), and other beams, and it becomes possible to separate the micro structures M from the first opposite face 1a.

The second plate-like member 2 is constituted by a release substrate or the like formed into a plate shape with opaque hard composite resin or transparent or translucent soft composite resin. Further, the transparent or translucent second plate-like member 2 includes a second plate-like member 2 made of a soft material which has low rigidity and is deformable such as a cyclic olefin ring-opening polymerization/hydrogenated product (COP) or ultra-thin glass (UTG).

The overall shape of the second plate-like member 2 is formed into a circular wafer shape or a rectangular panel shape. With regard to the sizes of the second plate-like member 2, the sizes thereof in a width direction/a length direction (XY directions), and a thickness direction (Z direction) are preferably substantially equal to or larger than those of the first plate-like member 1.

In the second plate-like member 2, a second opposite face 2a which faces the first plate-like member 1 in the Z direction is formed as a smooth face as a whole, and has a sticky layer 21 which faces surfaces Ma of the micro structures M.

The sticky layer 21 is formed of a material which has adhesion and is elastically deformable in the Z direction so as to have a uniform thickness along the second opposite face 2a. The thickness of the sticky layer 21 is set so as to allow the surfaces Ma of the micro structures M to be embedded to a predetermined depth from an outer surface of the sticky layer 21.

The pressure part 3 is a pressing machine which presses the micro structures M detachably bonded to the first opposite face 1a of the first plate-like member 1 via the temporary adhesion layer 11 toward the sticky layer 21 of the second opposite face 2a of the second plate-like member 2 in the thickness direction (Z direction) to cause the micro structures M to relatively approach the sticky layer 21.

The pressure part 3 has a pressing portion 3a which comes into contact with one of the first plate-like member 1 and the second plate-like member 2, and presses the one of the first plate-like member 1 and the second plate-like member 2 toward the other one thereof.

The pressing portion 3a comes into contact with the entire face or part of a first non-opposite face 1b of the first plate-like member 1 or the entire face or part of a second non-opposite face 2b of the second plate-like member 2 and performs pressing in the Z direction such that the first opposite face 1a and the temporary adhesion layer 11 of the first plate-like member 1 and the second opposite face 2a and the sticky layer 21 of the second plate-like member 2 become parallel to each other at least locally (completely or partially).

Note that, when pressing by the pressing portion 3a is performed, there are cases where, in the first plate-like member 1 to which the micro structures M are bonded via the temporary adhesion layer 11, plastic deformation occurs in unsmoothed portions in the entire face of, part of, or a curved face of the first opposite face 1a due to warpage or roughness. In these cases, by performing pressing with the pressing portion 3a such that the entire face or part of the temporary adhesion layer 11 and the entire face or part of the sticky layer 21 become parallel to each other, the shape of the plastic deformation of the first plate-like member 1 is modified (corrected) along the smooth second opposite face 2a, and the second opposite face 2a is deformed along the plastic deformation of the first plate-like member 1.

With this operation of the pressing portion 3a, the micro structures M which were detachably bonded to the first opposite face 1a of the first plate-like member 1 via the temporary adhesion layer 11 are pressed into the sticky layer 21 in a state in which at least the entire surfaces Ma are evenly pressed, and the micro structures M are adhered in a state in which the surfaces Ma are embedded in the sticky layer 21.

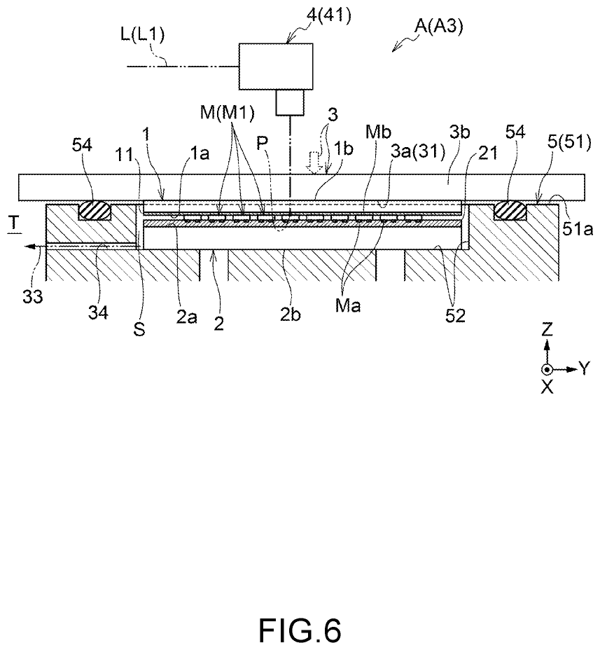

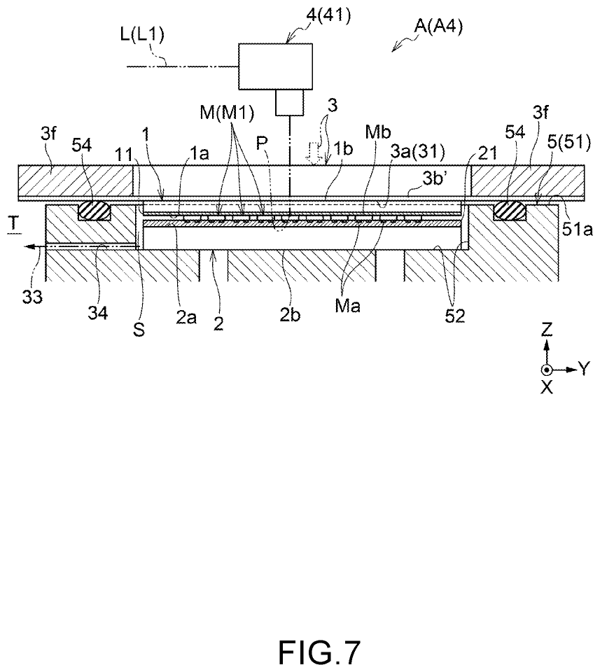

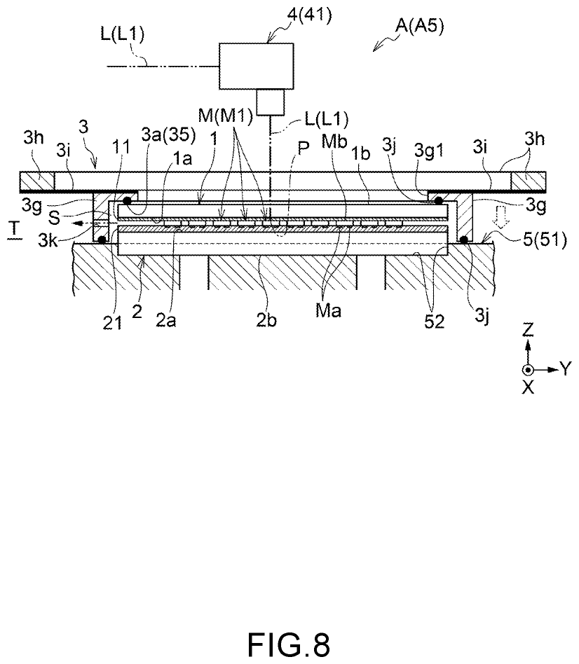

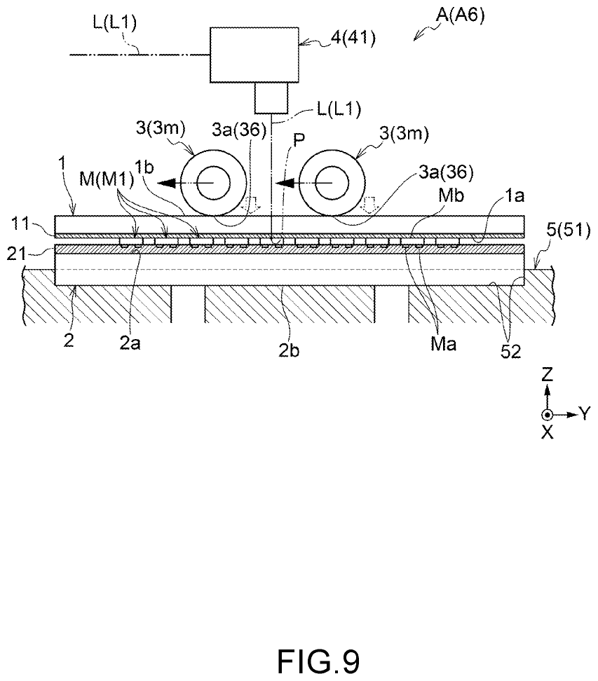

Methods of pressing the micro structures M into the sticky layer 21, i.e., specific examples of the pressing portion 3a include an entire face pressing method having a surface pressing portion 31 shown in each of FIGS. 1 to 7, a partial pressing method having a frame-like pressing portion 35 shown in FIG. 8, and a moving pressing method having moving pressing portions 36 and 37 shown in each of FIGS. 9 and 10. In addition, the methods are divided into a mechanical pressing type in which the pressing portion 3a shown in each of FIGS. 1 to 5 and FIGS. 8 to 10 is mechanically moved and pressing is thereby performed, and a pressure difference type in which the pressing portion 3a shown in each of FIGS. 6 and 7 is moved by a difference in pressure between the inside and the outside of the space S and pressing is thereby performed.

The denaturing/peeling part 4 is a peeling mechanism for changing (denaturing) properties of the temporary adhesion layer 11 such that an adhesive force of the temporary adhesion layer 11 is reduced with irradiation with the light L such as the laser beam L1, the heat ray (infrared light), and other beams, and allowing the micro structures M to be peeled from the temporary adhesion layer 11.

The denaturing/peeling part 4 has a light irradiation portion 41 which irradiates the light L toward the temporary adhesion layer 11 through the transparent or translucent first plate-like member 1 or second plate-like member 2, and a relative movement portion 42 which moves a light irradiation position P from the light irradiation portion 41 to the entire face of the temporary adhesion layer 11 relatively in the XY directions.

The light irradiation portion 41 preferably changes the properties of the temporary adhesion layer 11 with the irradiation with the laser beam L1 serving as the light L such that the temporary adhesion layer 11 can be peeled by a slight external force. In this case, the light irradiation portion 41 is provided as part of an optical system (not shown) which guides the laser beam L1 from a laser oscillator (not shown) serving as a light source toward the thickness direction (Z direction) to the temporary adhesion layer 11.

The relative movement portion 42 is an optical axis movement mechanism which moves one of the temporary adhesion layer 11 and the light irradiation portion 41 or both of the temporary adhesion layer 11 and the light irradiation portion 41, and is configured to perform relative movement at least in two directions (XY directions) intersecting an irradiation direction (Z direction) of the light L from the light irradiation portion 41.

In the case of the example shown in each of FIGS. 1 to 5, the light irradiation portion 41 is fixed and disposed, and an XY stage or the like which relatively moves the first plate-like member 1 in XYθ directions is used as the relative movement portion 42.

In addition, although not shown, as other examples, the structure shown as the example in the drawing can be changed to structures other than the structure shown as the example in the drawing such as a structure in which the properties of the temporary adhesion layer 11 are changed such that the temporary adhesion layer 11 can be peeled by irradiation with a heat ray (infrared light) and other beams instead of the laser beam L1, and a structure in which only the light irradiation portion 41 is relatively moved as the relative movement portion 42. Further, it is also possible to use a laser scanner which moves the optical axis (principal axis) of the laser beam L1 as the light irradiation portion 41, and move the light irradiation position P from the light irradiation portion 41 relatively in the XY directions by using the XY stage serving as the relative movement portion 42 in combination with the laser scanner.

The supporting part 5 is a support mechanism which supports the first plate-like member 1 and the second plate-like member 2 transported toward the apparatus main body B by a transport mechanism (not shown) described later such that the first plate-like member 1 and the second plate-like member 2 face each other in the thickness direction (Z direction).

The space S required to house the first plate-like member 1 and the second plate-like member 2 is formed in the vicinity of the supporting part 5 (in an upper part in an example shown in the drawing).

The supporting part 5 has a supporting stand 51 for the first plate-like member 1 and the second plate-like member 2. It is preferable that the supporting stand 51 is provided in the apparatus main body B, and has a concave part 52 which is placed on its outer surface to prevent positional displacement of the first plate-like member 1 and the second plate-like member 2 in the XY directions.

In the case of an examples shown in FIGS. 1 to 5, a lift mechanism 53 constituted by a lift pin or the like which receives the first plate-like member 1 and the second plate-like member 2 which are carried in and are not yet transferred and guides the first plate-like member 1 and the second plate-like member 2 to the concave part 52 is provided so as to pass through the supporting stand 51. The concave part 52 is formed such that the second plate-like member 2 serving as a lower transfer destination is placed so as not to be movable in the XY directions. The supporting stand 51 is made movable with respect to the apparatus main body B in the XYθ directions by the relative movement portion 42 such as the XY stage.

In addition, although not shown as another example, it is also possible to change the structure of the supporting part 5 to a structure other than the structure shown as the example in the drawing.

The controlling part 6 is a controller having a controlling circuit (not shown) electrically connected to the pressure part 3, the denaturing/peeling part 4, and the supporting part 5.

Further, the controlling part 6 is also electrically connected to a transport mechanism (not shown) for carrying the first plate-like member 1 and the second plate-like member 2 before being transferred toward the supporting part 5 and carrying the first plate-like member 1 and the second plate-like member 2 after being transferred out from the supporting part 5.

The controller serving as the controlling part 6 controls operations sequentially at a preset timing according to a program which is set in advance in the controlling circuit.

Subsequently, a program set in the controlling circuit of the controlling part 6 will be described as a transfer method by the transfer apparatus A.

The transfer method which uses the transfer apparatus A according to the embodiment of the present invention includes, as main processes, a setting process of disposing the first plate-like member 1 such that the first plate-like member 1 faces the second plate-like member 2 in the thickness direction (Z direction), a pressing process of pressing one of the first plate-like member 1 and the second plate-like member 2 toward the other one thereof in the thickness direction (Z direction), and a denaturing process of changing properties of the temporary adhesion layer 11 such that the adhesive force of the temporary adhesion layer 11 is reduced.

Further, the transfer method preferably includes a carrying-in process of the first plate-like member 1 and the second plate-like member 2 as an upstream process of the setting process, and a carrying-out process of the first plate-like member 1 and the second plate-like member 2 as a downstream process of the denaturing process.

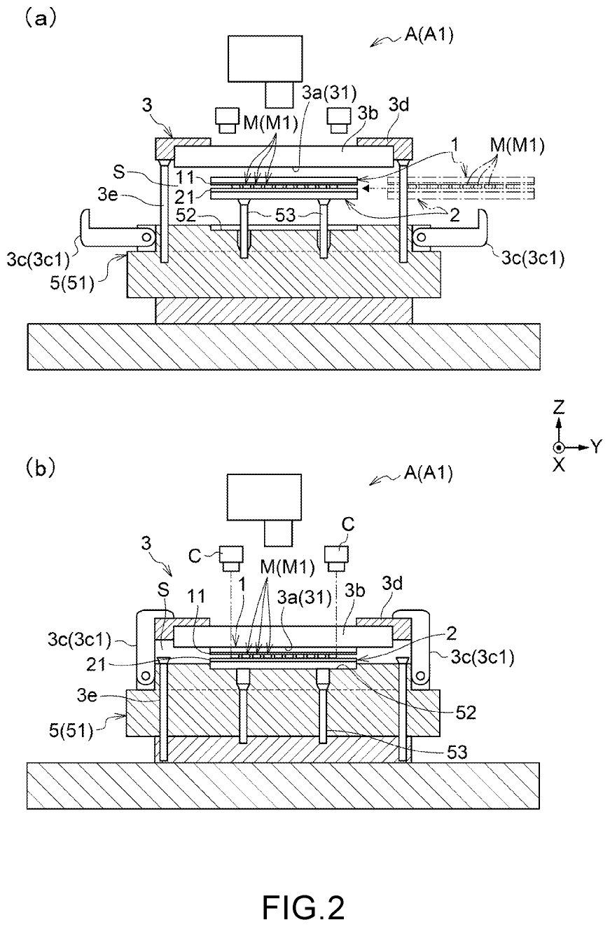

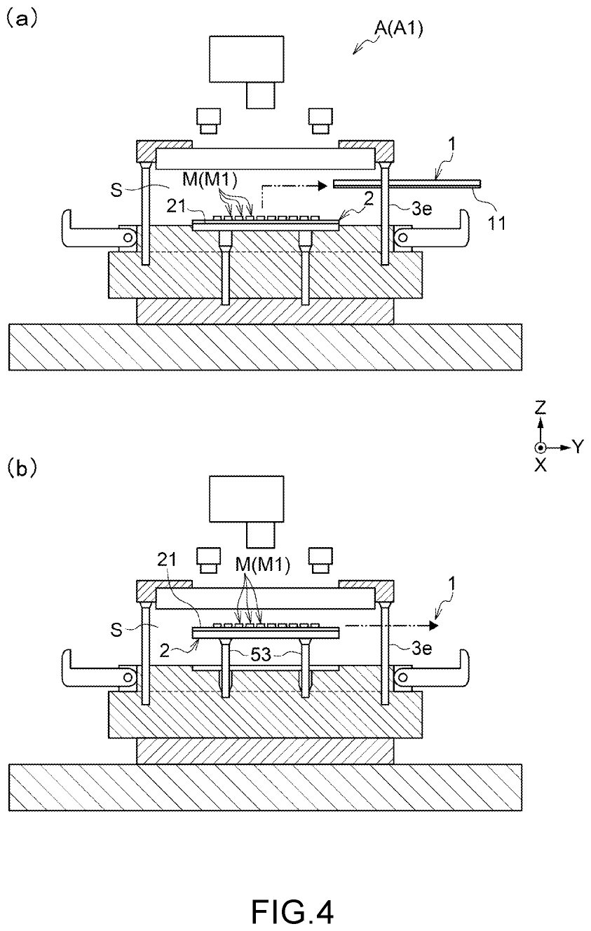

The transfer method from the carrying-in process to the carrying-out process will be described based on FIGS. 1 at (b) and 1 at (c) and FIG. 2 at (a) to FIG. 4 at (b). As shown in FIG. 2 at (a), in an initial state before the carrying-in process, the pressure part 3 is moved to a non-pressure standby position, and the space S required to house the first plate-like member 1 and the second plate-like member 2 is thereby formed.

In the carrying-in process, in the case of the examples shown in the drawings, with an operation of a transport mechanism (not shown) constituted by a transport robot or the like, the first plate-like member 1 and the second plate-like member 2 before being transferred are carried toward the space S in a state in which the first plate-like member 1 and the second plate-like member 2 are stacked.

Further, in addition to the examples shown in the drawings, it is possible to carry the first plate-like member 1 and the second plate-like member 2 separately toward the space S.

In the setting process, as shown in FIG. 2 at (b), the first plate-like member 1 and the second plate-like member 2 before being transferred are received by the lift mechanism 53 and are guided toward the concave part 52 of the supporting stand 51.

In the case of the examples shown in the drawings, the second plate-like member 2 serving as the lower transfer destination enters the concave part 52, and the second plate-like member 2 is thereby positioned so as not to be movable in the XY directions.

In the pressing process, as shown in FIGS. 1 at (b) and 1 at (c) and FIG. 2 at (b), the pressing portion 3a comes into contact with one of the first plate-like member 1 and the second plate-like member 2 and presses the one of the first plate-like member 1 and the second plate-like member 2 toward the other one thereof such that the temporary adhesion layer 11 and the sticky layer 21 become parallel to each other at least locally.

At this point, as indicated by a one-dot chain line in FIG. 2 at (b), it is preferable that the positions of the first plate-like member 1 and the micro structures M are detected by a position detector C such as a camera, and are adjusted finely based on the detection values by the relative movement portion 42.

With this, the surfaces Ma of the micro structures M detachably bonded to the first opposite face 1a of the first plate-like member 1 via the temporary adhesion layer 11 are pressed into the sticky layer 21 in a state in which the entire surfaces Ma are evenly pressed, and are embedded in and are adhered to the sticky layer 21.

In the case of the examples shown in the drawings, connection terminals serving as the surfaces Ma of the micro LED chips which are aligned and disposed as the micro structures M (micro structure bodies M1) are adhered so as to be embedded in the sticky layer 21.

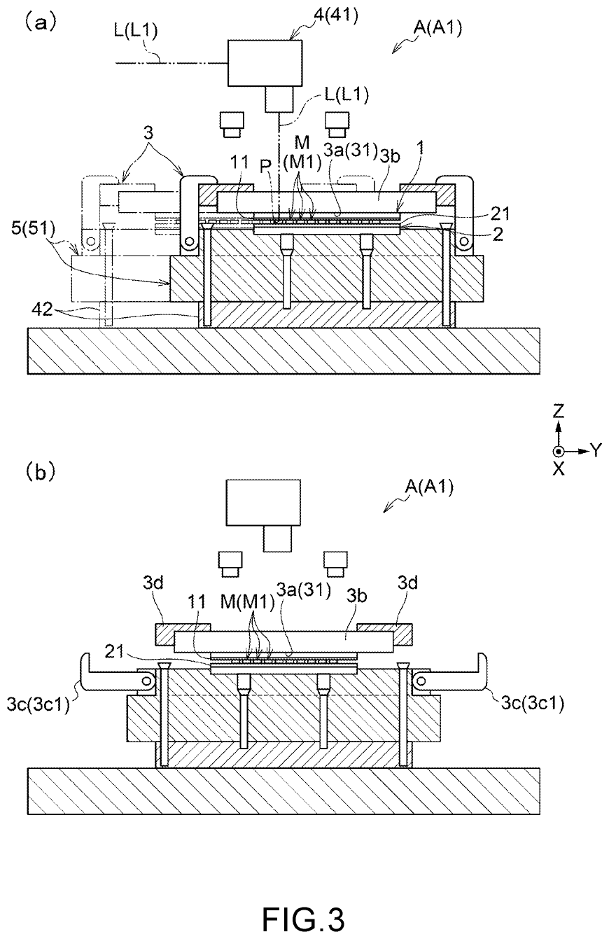

In the denaturing process, as shown in FIG. 1 at (b) and FIG. 3 at (a), the properties of the temporary adhesion layer 11 are changed (denatured) by the irradiation with the light L by the denaturing/peeling part 4 such that the adhesive force of the temporary adhesion layer 11 is reduced, and back surfaces Mb of the micro structures M are peeled from the temporary adhesion layer 11.

At this point, in the case of the examples shown in the drawings, the laser beam L1 passes through the transparent or translucent first plate-like member 1 and is irradiated to the temporary adhesion layer 11 from the light irradiation portion 41 and, at the same time, the first plate-like member 1 and the second plate-like member 2 are relatively moved in the XYθ directions via the supporting stand 51 by the XI stage serving as the relative movement portion 42, whereby the laser beam L1 is irradiated to the entire face of the temporary adhesion layer 11.

With this, the micro structures M are transferred to the sticky layer 21 of the second plate-like member 2 from the temporary adhesion layer 11 in a state in which the surfaces Ma of the micro structures M are embedded in the sticky layer 21.

After completion of the denaturing process, as shown in FIG. 3 at (b), pressing by the pressing portion 3a is released.

In the carrying-out process, as shown in FIG. 4 at (a) and FIG. 4 at (b), the first plate-like member 1 and the second plate-like member 2 after being transferred are carried out sequentially from the space S.

Thereafter, the above-described operations are repeated.

Next, a description will be given of the transfer apparatus A according to each of first to seventh embodiments of the present invention.

In a transfer apparatus A1 of the first embodiment shown in each of FIGS. 1 to 4, the pressing portion 3a of the pressure part 3 uses the entire face pressing method having the surface pressing portion 31, and the entire first plate-like member 1 is pressed by the surface pressing portion 31 and the temporary adhesion layer 11 and the sticky layer 21 are thereby caused to approach each other relatively.

The surface pressing portion 31 is formed smoothly along a tip face of a plate-like body 3b which is formed of a non-deformable rigid material so as to have a size substantially equal to or larger than the size of the first plate-like member 1, and comes into contact with the entire first non-opposite face 1b and presses the first non-opposite face 1b.

In the case of examples shown as specific examples of the surface pressing portion 31 in FIGS. 1 at (a), 1 at (b), and 1 at (c) to FIGS. 4 at (a) and 4 at (b), the plate-like body 3b made of a transparent or translucent rigid material such as quartz glass, and a presser member 3c which presses the plate-like body 3b in the Z direction are provided. The light L (laser beam L1) from the light irradiation portion 41 passes through the transparent or translucent plate-like body 3b and the first plate-like member 1, and is irradiated to the temporary adhesion layer 11.

The presser member 3c is a jig of the mechanical pressing type which mechanically presses the first plate-like member 1 toward the second plate-like member 2 in the Z direction with the plate-like body 3b.

In each example shown in the drawings, it is preferable that a pressure frame 3d is attached to an outer peripheral part of the plate-like body 3b, and a plurality of the presser members 3c are disposed in the pressure frame 3d at predetermined intervals in a circumferential direction.

The presser members 3c in the example shown in the drawing are clamps 3c1 which are swingably provided to extend over the pressure frame 3d and the supporting stand 51 of the supporting part 5. The clamps 3c1 are engaged with the pressure frame 3d by an operation of its driving part (not shown) or work performed in advance by a worker, and the plate-like body 3b is thereby caused to perform approaching movement such that the plate-like body 3b presses the entire face of the first plate-like member 1 toward the second plate-like member 2 in the Z direction.

With the operation of the presser members 3c (clamps 3c1), it becomes possible to press the first plate-like member 1 toward the second plate-like member 2 with the surface pressing portion 31 of the plate-like body 3b such that the temporary adhesion layer 11 and the sticky layer 21 become parallel to each other completely. Accordingly, it is possible to press the surfaces Ma of the micro structures M which are detachably held in the first plate-like member 1 with the temporary adhesion layer 11 into the sticky layer 21 in the state in which the entire surfaces Ma are evenly pressed.

In addition, in the example shown in the drawing, a pressure release mechanism 3e constituted by lift pins or the like is provided in order to move the plate-like body 3b and the pressure frame 3d of the pressure part 3 to non-pressure standby positions.

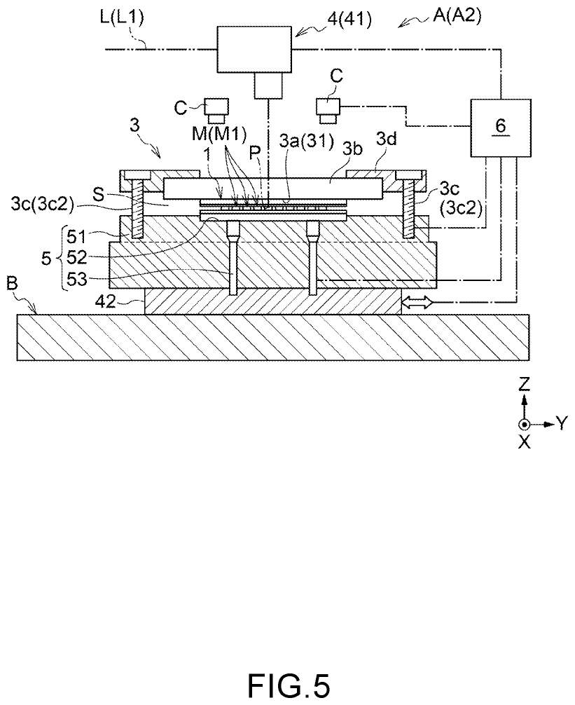

A transfer apparatus A2 of the second embodiment shown in FIG. 5 is different from that of the first embodiment described above in a configuration in which a lifting lever 3c2 is provided to extend over the pressure frame 3d and the supporting stand 51 of the supporting part 5 as the presser member 3c of the pressure part 3, and the other configurations thereof are the same as those of the first embodiment.

The lifting lever 3c2 is threaded as lifting means of the pressure frame 3d and, by rotating the lifting lever 3c2 by an operation of its driving part (not shown) or work performed in advance by a worker, the plate-like body 3b is caused to perform approaching movement such that the plate-like body 3b presses the first plate-like member 1 toward the second plate-like member 2 in the Z direction.

With the operation of the lifting lever 3c2, it becomes possible to press the first plate-like member 1 toward the second plate-like member 2 with the surface pressing portion 31 of the plate-like body 3b such that the temporary adhesion layer 11 and the sticky layer 21 become parallel to each other completely.

A transfer apparatus A3 of the third embodiment shown in FIG. 6 is different from those of the first embodiment and the second embodiment described above in a configuration in which the pressing portion 3a of the pressure part 3 is the pressure difference type which uses a difference in pressure between the inside and the outside of the space S, and the other configurations thereof are the same as those of the first embodiment and the second embodiment.

The pressing portion 3a of the pressure difference type has the space S having a sealed structure which houses the first plate-like member 1 and the second plate-like member 2 airtightly, and a pressure-adjusting part 33 which adjusts internal pressure of the space S.

The space S having the sealed structure is configured such that the first plate-like member 1 is movable toward the second plate-like member 2 in the Z direction at least in the pressing process. In the space S, a passage 34 is formed so as to communicate with an airtight inner area which houses the first plate-like member 1 and the second plate-like member 2, and an external space T formed outside the space S.

The pressure-adjusting part 33 has a drive source for pressure adjustment (not shown) such as, e.g., a vacuum pump or a compressor and, by sucking gas (air) in the space S by the operation of the drive source for pressure adjustment and discharging the sucked gas to the external space T, the internal pressure of the space S is reduced, and it becomes possible to set atmospheres from an air atmosphere to a vacuum or a low-pressure atmosphere close to a vacuum, and a predetermined high-pressure atmosphere. In addition, it is also possible to increase the internal pressure of the space S by the operation of the pressure-adjusting part 33 which is reverse to the above-described operation.

In the example shown in the drawing, similarly to the first embodiment and the second embodiment, the entire face pressing method having the surface pressing portion 31 is used, an elastically deformable seal member 54 such as an O ring is held between a tip face of the plate-like body 3b in which the surface pressing portion 31 is formed and the supporting stand 51 of the supporting part 5, and sealing is thereby performed.

Accordingly, the plate-like body 3b is caused to perform approaching movement toward the supporting stand 51 in the Z direction by a reduction in the pressure of the space S by the operation of the pressure-adjusting part 33, whereby the entire first plate-like member 1 is pressed by the surface pressing portion 31 of the plate-like body 3b, and the temporary adhesion layer 11 and the sticky layer 21 are caused to approach each other relatively.

With this, in the pressing portion 3a of the pressure difference type, similarly to the mechanical pressing type, it becomes possible to press the first plate-like member 1 toward the second plate-like member 2 such that the temporary adhesion layer 11 and the sticky layer 21 become parallel to each other entirely. Accordingly, it is possible to press the surfaces Ma of the micro structures M which are detachably held in the first plate-like member 1 with the temporary adhesion layer 11 into the sticky layer 21 in the state in which the entire surfaces Ma are evenly pressed.

Further, even when gas is generated due to the change of properties of the temporary adhesion layer 11 by the irradiation with the light L (laser beam L1), it becomes possible to suck gas in the space S from the passage 34, and discharge the sucked gas to the external space T to remove the sucked gas. Accordingly, the pressing pressure of the first plate-like member 1 to the second plate-like member 2 becomes less likely to change, and also it is possible to perform peeling having little contamination.

A transfer apparatus A4 of the fourth embodiment shown in FIG. 7 is different from that of the third embodiment described above in a configuration in which the pressing portion 3a of the pressure part 3 uses the entire face pressing method having the surface pressing portion 31 of a plate-like body 3b′ having a small thickness, and the other configurations thereof are the same as those of the third embodiment.

As the surface pressing portion 31 of the plate-like body 3b′ having a small thickness, by using the pressure difference type described in the transfer apparatus A3 of the third embodiment, even the surface pressing portion 31 of the plate-like body 3b′ having a small thickness can press the entire first plate-like member 1 to cause the temporary adhesion layer 11 and the sticky layer 21 to approach each other relatively.

As the plate-like body 3b′ having a small thickness, it becomes possible to use a thin resin plate or ultra-thin glass formed of a transparent or translucent soft material having low rigidity such as the COP or the UTG. A frame-like member 3f for reinforcement is fixed to an outer peripheral part of the plate-like body 3b′ having a small thickness, the outer peripheral part of the plate-like body 3b′ which is made non-deformable by the frame-like member 3f for reinforcement is caused to face a stand surface 51a of the supporting stand 51 in which the seal member 54 is disposed, and sealing is thereby performed reliably.

The light L (laser beam L1) from the light irradiation portion 41 passes through the transparent or translucent plate-like body 3b′ having a small thickness and first plate-like member 1, and is irradiated to the temporary adhesion layer 11.

With this, as compared with each of the first to third embodiments in which the light L (laser beam L1) passes through the plate-like body 3b having a large thickness and the first plate-like member 1 and is irradiated to the temporary adhesion layer 11, it becomes possible to reduce energy loss of the light L (laser beam L1) and allow efficient laser irradiation.

A transfer apparatus A5 of the fifth embodiment shown in FIG. 8 is different from those of the first to fourth embodiments described above in a configuration in which the pressing portion 3a of the pressure part 3 uses the partial pressing method having the frame-like pressing portion 35, and the first plate-like member 1 is partially pressed by the frame-like pressing portion 35 and the temporary adhesion layer 11 and the sticky layer 21 are thereby caused to approach each other relatively, and the other configurations thereof are the same as those of the first to fourth embodiments.

The frame-like pressing portion 35 is formed smoothly along an inner tip face of a frame-like body 3g which is formed of a non-deformable rigid material so as to have a size larger than the size of the first plate-like member 1, and partially comes into contact with an outer peripheral part of the first non-opposite face 1b and presses the outer peripheral part thereof.

In the case of an example shown in the drawing as a specific example of the frame-like pressing portion 35, a lifting member 3h of the mechanical pressing type which mechanically presses the first plate-like member 1 toward the second plate-like member 2 in the Z direction with the frame-like body 3g is provided. The light L (laser beam L1) from the light irradiation portion 41 passes through an opening 3g1 provided in the center of the frame-like body 3g and also passes through only the transparent or translucent first plate-like member 1, and is irradiated to the temporary adhesion layer 11.

With this, the light L (laser beam L1) passes through only the first plate-like member 1 and is irradiated to the temporary adhesion layer 11, and hence, as compared with the fourth embodiment in which the light L passes through the plate-like body 3b′ having a small thickness and the first plate-like member 1 and is irradiated to the temporary adhesion layer 11, it is possible to further reduce the energy loss of the light L (laser beam L1) and perform irradiation.

The lifting member 3h is a lifting mechanism configured to press the first plate-like member 1 toward the second plate-like member 2 in the Z direction via the frame-like body 3g, and the lifting member 3h formed into a frame shape and the frame-like body 3g are coupled to each other with a diaphragm 3i constituted by an elastic material such as a plate spring. The lifting member 3h is caused to perform upward or downward movement by an operation of its driving part (not shown) or work performed in advance by a worker, and the frame-like body 3g thereby causes the first plate-like member 1 and the second plate-like member 2 to perform approaching movement such that the frame-like body 3g presses the first plate-like member 1 toward the second plate-like member 2 in the Z direction via the diaphragm 3i.

With the operation of the lifting member 3h, it becomes possible to press the first plate-like member 1 toward the second plate-like member 2 with the frame-like pressing portion 35 of the frame-like body 3g such that the temporary adhesion layer 11 and the sticky layer 21 become parallel to each other entirely.

Further, in the transfer apparatus A5 of the fifth embodiment, similarly to the third embodiment and the fourth embodiment, the space S which houses the first plate-like member 1 and the second plate-like member 2 is configured to have a sealed structure. In the frame-like body 3g in the example shown in the drawing, the first plate-like member 1 is formed between the diaphragm 3i and the supporting stand 51 of the supporting part 5 so as to surround the periphery of the second plate-like member 2, sealing is performed with a seal member 3j such as an O ring, and a through hole 3k which causes the space S to communicate with the external space is opened. Consequently, the pressing pressure of the first plate-like member 1 to the second plate-like member 2 becomes less likely to change, and also it is possible to perform peeling with little contamination.

A transfer apparatus A6 of the sixth embodiment shown in FIG. 9 is different from those of the first to fifth embodiments described above in a configuration in which the pressing portion 3a of the pressure part 3 uses a moving pressing method (mechanical pressing type) having a moving pressing portion 36, and the first plate-like member 1 is partially pressed by the moving pressing portion 36 and the temporary adhesion layer 11 and the sticky layer 21 are thereby caused to approach each other relatively, and the other configurations thereof are the same as those of the first to fifth embodiments.

The moving pressing portion 36 is formed smoothly along a tip of a bar-like body 3m formed into a rod shape having a size larger than the width in one of the XY directions of the first plate-like member 1, and partially comes into contact with the first non-opposite face 1b and presses the first non-opposite face 1b.

In the case of an example shown in the drawing as a specific example of the moving pressing portion 36, the bar-like body 3m which is formed into a circular cylindrical shape (roll shape) or a prismatic shape longer than the width of the first plate-like member 1, and a pressing structure (not shown) of the mechanical pressing type which mechanically presses the first plate-like member 1 toward the second plate-like member 2 in the Z direction with the bar-like body 3m are provided. The pressing structure of the bar-like body 3m is configured such that, by relatively moving the bar-like body 3m with respect to the first non-opposite face 1b of the first plate-like member 1 in a direction intersecting one of the XY directions, approaching movement is performed such that the entire face of the first plate-like member 1 is pressed toward the second plate-like member 2 in the Z direction by the weight of the bar-like body 3m.

In an example shown in the drawing, the bar-like body 3m is a roller in which an outer peripheral face of a spindle made of a non-deformable rigid material is covered with a skin layer made of an elastically deformable material such as rubber and, by moving the bar-like body 3m in synchronization with relative irradiation movement of the light L (laser beam L1) from the light irradiation portion 41 with respect to the first plate-like member 1, the light L (laser beam L1) is irradiated to the entire face of the temporary adhesion layer 11.

With the operation of the bar-like body 3m, it becomes possible to press the first plate-like member 1 toward the second plate-like member 2 with the moving pressing portion 36 such that the temporary adhesion layer 11 and the sticky layer 21 become parallel to each other partially.

With this, even when the size of the first plate-like member 1 or the second plate-like member 2 is large (large area), it becomes possible to simultaneously perform pressing of the micro structures M into the sticky layer 21 by the bar-like body 3m and peeling of the micro structures M from the temporary adhesion layer 11 by irradiation with the light L (laser beam L1). Accordingly, even when the size of the first plate-like member 1 or the second plate-like member 2 is large (large area), unevenness becomes less likely to occur in an adhesion state and a peeling state of the micro structures M.

In particular, it is preferable that a pair of the bar-like bodies 3m are provided so as to hold the light L (laser beam L1) from the light irradiation portion 41 therebetween, and a pair of the bar-like bodies 3m are disposed so as to be close to the light irradiation position P of the light L (laser beam L1).

In this case, it is possible to perform pressing of the micro structures M at close positions at irradiation timings of the light L (laser beam L1), and hence, even when warpage deformation or roughness deformation is present in the first plate-like member 1, unevenness becomes further less likely to occur in the adhesion state and the peeling state of the micro structures M.

A transfer apparatus A7 of the seventh embodiment shown in FIG. 10 is different from that of the sixth embodiment described above in a configuration in which a sticky layer 21′ of the deformable second plate-like member 2 is pressed toward a temporary adhesion layer 11′ in the thickness direction (Z direction) by the pressing portion 3a of the pressure part 3, and the other configurations thereof are the same as those of the sixth embodiment.

The first plate-like member 1 has a first opposite face 1a′ on which the temporary adhesion layer 11′ is provided, and the second plate-like member 2 has a second opposite face 2a′ on which the sticky layer 21′ is provided.

In an example shown in the drawing, the first plate-like member 1 serving as the transfer source is disposed in a lower part, and the second plate-like member 2 made of a thin low-rigidity soft material such as the COP or the UTG is disposed in an upper part.

Further, the pressing portion 3a of the seventh embodiment uses the moving pressing method (mechanical pressing type) having a second moving pressing portion 37 having a structure similar to that of the moving pressing portion 36 of the sixth embodiment and, by relatively moving the bar-like body 3m with respect to a second non-opposite face 2b′ of the second plate-like member 2, approaching movement is performed such that the entire face of the second plate-like member 2 is pressed toward the first plate-like member 1 in the Z direction by the weight of the bar-like body 3m.

With the operation of the bar-like body 3m, it becomes possible to press the second plate-like member 2 toward the first opposite face 1a′ with the second moving pressing portion 37 such that the sticky layer 21′ and the temporary adhesion layer 11′ become parallel to each other partially.

With regard to the denaturing/peeling part 4 of the seventh embodiment, the light L (laser beam L1) from the light irradiation portion 41 or the like passes through the transparent or translucent first plate-like member 1 and is irradiated to the temporary adhesion layer 11.

In addition, although not shown in the drawing as another example, it is possible to change the method of the pressing portion 3a of the pressure part 3 to the entire face pressing method having the surface pressing portion 31, and the partial pressing method having the frame-like pressing portion 33.

According to the transfer apparatus A and the transfer method according to the embodiments of the present invention described above, first, one of the first plate-like member 1 and the second plate-like member 2 is pressed toward the other one thereof in the thickness direction (Z direction) by the pressure part 3 such that the temporary adhesion layer 11 and the sticky layer 21 of the second plate-like member 2 become parallel to each other at least locally.

With this, the surfaces Ma of the micro structures M which are detachably held in the first plate-like member 1 via the temporary adhesion layer 11 are pressed into the sticky layer 21 in the state in which the entire surfaces Ma are evenly pressed, and are embedded in and adhered to the sticky layer 21.

Next, by changing properties of the temporary adhesion layer 11 with the denaturing/peeling part 4 while maintaining the embedded state of the micro structures M, the micro structures M (the back faces Mb thereof) are peeled from the temporary adhesion layer 11. Concurrently with this, the surfaces Ma of the micro structures M are transferred to the second plate-like member 2 in the state in which the surfaces Ma of the micro structures M are embedded in the sticky layer 21.

Consequently, it is possible to transfer the micro structures M from the temporary adhesion layer 11 to the sticky layer 21 of the second plate-like member 2 without causing posture collapse irrespective of plastic deformation such as warpage or roughness of the first plate-like member 1.

As a result, as compared with the conventional art in which irradiation unevenness of laser light partially occurs easily in the separation layer of the laminated body, even when the plastic deformation such as warpage or roughness is present in the first plate-like member 1, unevenness does not occur in the adhesion state of the micro structures M, and it is possible to prevent peeling failure of the micro structures M.

Further, the surfaces Ma of the micro structures M are embedded in the sticky layer 21 of the second plate-like member 2, and hence positional displacements do not occur at the time of peeling of the micro structures M caused by change of properties of the temporary adhesion layer 11 by the denaturing/peeling part 4, and it is possible to implement high-accuracy transfer. Consequently, it is possible to achieve an improvement in yield.

In particular, it is preferable that a plurality of the micro structures M are aligned and disposed in parallel with each other in the first plate-like member 1 via the temporary adhesion layer 11.

In this case, by pressing of the first plate-like member 1 by the pressure part 3, the surfaces Ma of a plurality of the micro structures M aligned and disposed in the first plate-like member 1 are pressed into the sticky layer 21 of the second plate-like member 2 such that the surfaces Ma become parallel to the sticky layer 21. Consequently, the surfaces Ma of a plurality of the micro structures M are embedded in and are adhered to the sticky layer 21.

Subsequently to this, by changing the properties of the temporary adhesion layer 11 with the denaturing/peeling part 4, a plurality of the micro structures M (the back faces Mb thereof) are peeled from the temporary adhesion layer 11. Concurrently with this, the surfaces Ma of a plurality of the micro structures M in the state in which the surfaces Ma thereof are embedded in the sticky layer 21 are transferred to the second plate-like member 2.

Consequently, it is possible to uniformly transfer a plurality of the micro structures M to the sticky layer 21 of the second plate-like member 2 from the temporary adhesion layer 11.

As a result, unevenness does not occur in the adhesion state of a plurality of the micro structures M, and it is possible to prevent peeling failure of each of a plurality of the micro structures M.

Further, the surfaces Ma of a plurality of the micro structures M are embedded in the sticky layer 21 of the second plate-like member 2, and hence the positional displacement does not occur at the time of peeling of a plurality of the micro structures M caused by the change of properties of the temporary adhesion layer 11 by the denaturing/peeling part 4, and it is possible to implement high-accuracy transfer. Consequently, it is possible to achieve a further improvement in yield.

Further, the denaturing/peeling part 4 is preferably an irradiation mechanism of the light L including the laser beam L1.

In this case, the light L such as the laser beam L1 irradiated from the denaturing/peeling part 4 passes through the transparent or translucent first plate-like member 1 or second plate-like member 2 and is irradiated to the temporary adhesion layer 11.

With this, the properties of the temporary adhesion layer 11 are changed and the micro structures M are peeled from the temporary adhesion layer 11 and, at the same time, the surfaces Ma of the micro structures M are transferred to the second plate-like member 2 in the state in which the surfaces Ma of the micro structures M are embedded in the sticky layer 21.

Consequently, it is possible to reliably peel the micro structures M from the temporary adhesion layer 11 by the irradiation with the light L including the laser beam L1, and transfer the micro structures M to the sticky layer 21 of the second plate-like member 2.

As a result, as compared with the conventional art in which irradiation unevenness of the laser light are apt to partially occur in the separation layer of the laminated body, the output of the light L such as the laser beam L1 does not become excessively high, damage to a device formed in the micro structures M is not caused, and the generation of soot by partial excessive irradiation does not occur.

Accordingly, it is possible to implement high-accuracy transfer of the micro structures M from the first plate-like member 1 to the second plate-like member 2, and achieve manufacturing of high-performance and clean products.

Further, as compared with the conventional art in which the beam homogenizer corresponding to the size and the locations of the LED chips are used, it is not necessary to prepare the homogenizer, it is possible to alleviate irradiation positioning accuracy of the light L (laser beam) such as the laser beam L1, and it is possible to increase the speed of an irradiation tact.

In addition, when the surfaces Ma of the micro structures M are embedded in the sticky layer 21 of the second plate-like member 2, it is possible to control a degree of alleviation of a shock wave by the irradiation with the light L such as the laser beam L1 according to its pressing-in amount.

In the example shown in each of FIGS. 1 to 9, the pressure part 3 is configured to press the temporary adhesion layer 11 toward the sticky layer 21 of the second plate-like member 2 in the thickness direction (Z direction), the first plate-like member 1 has the first opposite face 1a on which the temporary adhesion layer 11 is provided, and the second plate-like member 2 has the smooth second opposite face 2a on which the sticky layer 21 is provided.

According to the transfer apparatuses A1, A2, A3, A4, A5, and AG of the first to sixth embodiments described above, by pressing the first opposite face 1a of the first plate-like member 1 toward the smooth second opposite face 2a of the second plate-like member 2 with the pressure part 3, the face shape of the first opposite face 1a is modified so as to conform to the smooth second opposite face 2a, and the micro structures M which are detachably held via the temporary adhesion layer 11 are pressed so as to be parallel to the sticky layer 21 extending along the smooth second opposite face 2a at least locally.

Accordingly, even when the plastic deformation such as warpage or roughness is present in the first plate-like member 1, the plastic deformation such as warpage or roughness of the first plate-like member 1 is corrected along the sticky layer 21 of the smooth second opposite face 2a by pressing by the pressure part 3, and the micro structures M are embedded in and is adhered to the sticky layer 21 so as to conform to the sticky layer 21 of the smooth second opposite face 2a.

Subsequently to this, the micro structures M (the back faces Mb thereof) are peeled by the change of the properties of the temporary adhesion layer 11 by the denaturing/peeling part 4 and, at the same time, the surfaces Ma of the micro structures M are transferred to the second plate-like member 2 in the state in which the surfaces Ma of the micro structures M are embedded in the sticky layer 21 of the smooth second opposite face 2a.

Consequently, it is possible to transfer the micro structures M from the temporary adhesion layer 11 of the first opposite face 1a of the first plate-like member 1 to the sticky layer 21 with the smooth second opposite face 2a of the second plate-like member 2 used as a reference face.

As a result, even when the plastic deformation such as warpage or roughness is present in the first plate-like member 1, it is possible to correct the plastic deformation along the smooth second opposite face 2a of the second plate-like member 2, and it is possible to perform transfer of the micro structures M which are not influenced by the plastic deformation such as warpage or roughness.

In particular, in the case where a plurality of the micro structures M are aligned and disposed in parallel with each other via the temporary adhesion layer 11 in the first plate-like member 1, it is possible to perform transfer of a plurality of the micro structures M which are aligned and disposed without the influence of the plastic deformation such as warpage or roughness.

In the example shown in FIG. 6 or FIG. 7, the space S in which the first plate-like member 1 and the second plate-like member 2 are housed airtightly is provided, and the pressure part 3 has the pressing portion 3a which presses one of the first plate-like member 1 and the second plate-like member 2 toward the other one thereof in the thickness direction (Z direction) with a difference in pressure between the inside and the outside of the space S.

According to the transfer apparatus A3 of the third embodiment or the transfer apparatus A4 of the fourth embodiment described above, the pressing portion 3a presses one of the first plate-like member 1 and the second plate-like member 2 toward the other one thereof in the thickness direction (Z direction) with the difference in pressure between the inside and the outside of the space S.

With this, the surfaces Ma of the micro structures M which are detachably held in the first plate-like member 1 via the temporary adhesion layer 11 are pressed into the sticky layer 21 in the state in which the entire surfaces Ma are evenly pressed, and is embedded in and adhered to the sticky layer 21.

Consequently, the micro structures M can be evenly pressed from the temporary adhesion layer 11 with the pressure difference so as to conform to the sticky layer 21.

As a result, even when the plastic deformation such as warpage or roughness is present in the first plate-like member 1, it is possible to make the adhesion state of the micro structures M uniform and prevent peeling failure of the micro structures M.

In the example shown in FIG. 10, the pressure part 3 is configured to press the sticky layer 21′ of the second plate-like member 2 toward the temporary adhesion layer 11′ in the thickness direction (Z direction), the first plate-like member 1 has the first opposite face 1a′ on which the temporary adhesion layer 11′ is provided, and the second plate-like member 2 has the second opposite face 2a′ which is made of the deformable material and on which the sticky layer 21′ is provided.

According to the transfer apparatus A7 of the seventh embodiment described above, by pressing the second opposite face 2a′ of the second plate-like member 2 toward the first opposite face 1a′ of the first plate-like member 1 with the pressure part 3, the face shape of the second opposite face 2a′ is modified so as to conform to the first opposite face 1a′, and the micro structures M which are detachably held via the temporary adhesion layer 11′ are pressed so as to be parallel to the sticky layer 21 extending along the second opposite face 2a′ at least locally.

Consequently, even when a plastic deformation such as warpage or roughness is present in the first plate-like member 1, the second opposite face 2a′ and the sticky layer 21′ are deformed by pressing by the pressure part 3 according to the plastic deformation such as warpage or roughness of the first opposite face 1a′ and the temporary adhesion layer 11′, and the micro structures M are embedded and adhered so as to conform to the plastic deformation such as warpage or roughness of the temporary adhesion layer 11′.

Subsequently to this, the micro structures M (the back face Mb thereof) are peeled by the change of the properties of the temporary adhesion layer 11′ by the denaturing/peeling part 4 and, at the same time, the surfaces Ma of the micro structures M are transferred to the second plate-like member 2 in the state in which the surfaces Ma of the micro structures M are embedded in the sticky layer 21′ of the second opposite face 2a′.

Consequently, it is possible to transfer the micro structures M from the temporary adhesion layer 11′ to the sticky layer 21′ of the second opposite face 2a′ of the second plate-like member 2 with the first opposite face 1a′ of the first plate-like member 1 used as the reference face.

As a result, even when the plastic deformation such as warpage or roughness of the first plate-like member 1 is present, the second opposite face 2a′ of the second plate-like member 2 can be deformed so as to conform to the plastic deformation such as warpage or roughness of the first plate-like member 1, and it is possible to perform transfer of the micro structures M which are not influenced by the plastic deformation such as warpage or roughness.

Note that, in the example shown in the drawing in each of the embodiments (the first to seventh embodiments) described above, the transfer source is the first plate-like member 1 and the transfer destination is the second plate-like member 2, but the present invention is not limited thereto and, conversely, the transfer source may be changed to the second plate-like member 2, and the transfer destination may be changed to the first plate-like member 1.

Further, as a method of pressing the micro structures M into the sticky layer 21, the entire face pressing method in each of FIGS. 1 to 7, the partial pressing method in FIG. 8, and the moving pressing method in each of FIGS. 9 and 10 are shown as examples, but the present invention is not limited thereto, and a pressing method other than the examples shown in the drawings may be used. In addition, only each of FIG. 6 and FIG. 7 shows the pressure difference type, but the mechanical pressing type shown in each of FIGS. 1 to 5 and FIGS. 8 to 10 may be changed to the pressure difference type.

In particular, in the entire face pressing method of each of the first and second embodiments, the plate-like body 3b and the pressure frame 3d are pressed by the presser member 3c (clamps 3c1, lifting levers 3c2), but the present invention is not limited thereto, and the plate-like body 3b and the pressure frame 3d may be pressed by the lifting member 3h and the diaphragm 3i described in the fifth embodiment.

In addition, the space S has the sealed structure in each of the third to fifth embodiments, but the present invention is not limited thereto and, in each of the first and second embodiments and the sixth and seventh embodiments, the space S may have the sealed structure similarly to each of the third to fifth embodiments.

### REFERENCE SIGNS LIST

A Transfer apparatus
1 First plate-like member
1a, 1a′ First opposite face
11, 11′ Temporary adhesion layer
2 Second plate-like member
2a, 2a′ Second opposite face
21, 21′ Sticky layer
3 Pressure part
3a Pressing portion
4 Denaturing/peeling part
6 Controlling part
L Light
L1 Laser beam
M Micro structure
Ma Surface

1. A transfer apparatus in which at least one micro structures attached to a first plate-like member is peeled from the first plate-like member, and is bonded and transferred to a second plate-like member facing the first plate-like member, the transfer apparatus comprising:
the first plate-like member in which the at least one micro structures are detachably held via a temporary adhesion layer;
the second plate-like member having a sticky layer which faces the first plate-like member and is elastically deformable in a thickness direction;
a pressure part which presses one of the first plate-like member and the second plate-like member toward another one of the first plate-like member and the second plate-like member in the thickness direction such that the temporary adhesion layer and the sticky layer become parallel to each other at least locally;
a denaturing/peeling part which changes a property of the temporary adhesion layer such that an adhesive force of the temporary adhesion layer is reduced; and
a controlling part which controls operations of the pressure part and the denaturing/peeling part, wherein
the controlling part performs control such that the property of the temporary adhesion layer is changed by the denaturing/peeling part in a state in which surface of the at least one micro structures are pressed into the sticky layer by the pressure part and the surface of the micro structure is embedded in the sticky layer.

2. The transfer apparatus according to claim 1, wherein a plurality of the at least one micro structures are aligned and disposed in parallel with each other in the first plate-like member via the temporary adhesion layer.

3. The transfer apparatus according to claim 2, wherein the denaturing/peeling part is an irradiation mechanism of light including a laser beam.

4. The transfer apparatus according to claim 3, wherein
the pressure part is configured to press the temporary adhesion layer of the first plate-like member toward the sticky layer of the second plate-like member in the thickness direction,
the first plate-like member has a first opposite face on which the temporary adhesion layer is provided, and
the second plate-like member has a smooth second opposite face on which the sticky layer is provided.

5. The transfer apparatus according to claim 3, further comprising:
a space in which the first plate-like member and the second plate-like member are housed airtightly, wherein
the pressure part has a pressing portion which presses one of the first plate-like member and the second plate-like member toward another one of the first plate-like member and the second plate-like member in the thickness direction with a difference in pressure between inside and outside of the space.

6. The transfer apparatus according to claim 1, 2 or 3 wherein
the pressure part is configured to press the sticky layer of the second plate-like member toward the temporary adhesion layer of the first plate-like member in the thickness direction,
the first plate-like member has a first opposite face on which the temporary adhesion layer is provided, and
the second plate-like member has a second opposite face which is made of a deformable material and on which the sticky layer is provided.

7. A transfer method which peels at least one micro structures attached to a first plate-like member from the first plate-like member, and bonds and transfers the micro structure to a second plate-like member facing the first plate-like member, the transfer method comprising:
setting by disposing the first plate-like member and the second plate-like member such that the first plate-like member having a temporary adhesion layer faces the second plate-like member having a sticky layer;
pressing by pressing one of the first plate-like member and the second plate-like member toward another one of the first plate-like member and the second plate-like member in a thickness direction such that the temporary adhesion layer and the sticky layer become parallel to each other at least locally; and
denaturing by changing a property of the temporary adhesion layer such that an adhesive force of the temporary adhesion layer is reduced, wherein
surfaces of the at least one micro structures are pressed by a pressure part so as to be embedded in the sticky layer in the pressing, and
the property of the temporary adhesion layer is changed by a denaturing/peeling part in a state in which the surface of the micro structure is embedded in the sticky layer in the denaturing.

8. The transfer apparatus according to claim 1, wherein the denaturing/peeling part is an irradiation mechanism of light including a laser beam.

9. The transfer apparatus according to claim 1, wherein
the pressure part is configured to press the temporary adhesion layer of the first plate-like member toward the sticky layer of the second plate-like member in the thickness direction,
the first plate-like member has a first opposite face on which the temporary adhesion layer is provided, and
the second plate-like member has a smooth second opposite face on which the sticky layer is provided.

10. The transfer apparatus according to claim 1, further comprising:
a space in which the first plate-like member and the second plate-like member are housed airtightly, wherein
the pressure part has a pressing portion which presses one of the first plate-like member and the second plate-like member toward another one of the first plate-like member and the second plate-like member in the thickness direction with a difference in pressure between inside and outside of the space.

11. The transfer apparatus according to claim 1 wherein the pressure part is configured to press the sticky layer of the second plate-like member toward the temporary adhesion layer of the first plate-like member in the thickness direction,
the first plate-like member has a first opposite face on which the temporary adhesion layer is provided, and
the second plate-like member has a second opposite face which is made of a deformable material and on which the sticky layer is provided.

12. The transfer apparatus according to claim 2, wherein
the pressure part is configured to press the temporary adhesion layer of the first plate-like member toward the sticky layer of the second plate-like member in the thickness direction,
the first plate-like member has a first opposite face on which the temporary adhesion layer is provided, and
the second plate-like member has a smooth second opposite face on which the sticky layer is provided.

13. The transfer apparatus according to claim 2, further comprising:
a space in which the first plate-like member and the second plate-like member are housed airtightly, wherein
the pressure part has a pressing portion which presses one of the first plate-like member and the second plate-like member toward another one of the first plate-like member and the second plate-like member in the thickness direction with a difference in pressure between inside and outside of the space.

14. The transfer apparatus according to claim 2 wherein
the pressure part is configured to press the sticky layer of the second plate-like member toward the temporary adhesion layer of the first plate-like member in the thickness direction,
the first plate-like member has a first opposite face on which the temporary adhesion layer is provided, and
the second plate-like member has a second opposite face which is made of a deformable material and on which the sticky layer is provided.

15. The transfer apparatus according to claim 8, wherein
the pressure part is configured to press the temporary adhesion layer of the first plate-like member toward the sticky layer of the second plate-like member in the thickness direction,
the first plate-like member has a first opposite face on which the temporary adhesion layer is provided, and
the second plate-like member has a smooth second opposite face on which the sticky layer is provided.

16. The transfer apparatus according to claim 8, further comprising:
a space in which the first plate-like member and the second plate-like member are housed airtightly, wherein
the pressure part has a pressing portion which presses one of the first plate-like member and the second plate-like member toward another one of the first plate-like member and the second plate-like member in the thickness direction with a difference in pressure between inside and outside of the space.

17. The transfer apparatus according to claim 8 wherein
the pressure part is configured to press the sticky layer of the second plate-like member toward the temporary adhesion layer of the first plate-like member in the thickness direction,
the first plate-like member has a first opposite face on which the temporary adhesion layer is provided, and
the second plate-like member has a second opposite face which is made of a deformable material and on which the sticky layer is provided.
